(19) United States
(12) Patent Application Publication
(10) Pub. No.: US 2010/0104755 A1
(43) Pub. Date: Apr. 29, 2010

(54) DEPOSITION METHOD OF TERNARY FILMS

(76) Inventors: Christian Dussarrat, Wilmington, DE (US); Kazutaka Yanagita, Ibaraki (JP); Julien Gatineau, Ibaraki (JP)

Correspondence Address: AIR LIQUIDE;Intellectual Property, 2700 POST OAK BOULEVARD, SUITE 1800, HOUSTON, TX, 77056, US

(21) Appl. No.: 11/993,570

(22) PCT Filed: Jun. 29, 2005
(86) PCT No.: PCT/EP2005/008196

§ 371 Date: Jan. 7, 2010

(51) Int. Cl. C23C 16/34; C23C 16/30

(52) U.S. Cl. 427/255.394; 427/255.23

(57) ABSTRACT

Method for producing a metal-containing film by introducing a metal source which does not contain metal-C or metal-N—C s-bonds (for example, TaCl<SUB>5</SUB>, SEt<SUB>2</SUB>), a silicon precursor (for example, SiH(NMe<SUB>2</SUB>)<SUB>3</SUB> or (SiH<SUB>3</SUB>)<SUB>3</SUB>N), a nitrogen precursor such as ammonia, a carbon source such as monomethylamine or ethylene and a reducing agent (for example, H<SUB>2</SUB>) into a CVD chamber and reacting same at the surface of a substrate to produce metal containing films in a single step.

### BACKGROUND

Manufacturing of semiconductor devices employs a thin transition metal-containing film (typically tantalum nitride or titanium nitride) between the underlying low-k dielectric layer and the copper lines used as a barrier to prevent copper poisoning of low-k dielectrics. It is expected that this type of film will be employed as well as a metal electrode in combination with high-k dielectric thin film in CMOS as it is already used as a top or bottom electrode for memory applications. Depositing a transition metal-containing film, with the generic formula MₓSi_{y}N_{z}Cₜ, on high-k or low-k films therefore forms either a gate electrode or a barrier layer. Typical processes for growth of metallic films include chemical vapor deposition, pulse chemical vapor deposition and atomic layer deposition processes. As integrated circuit devices sizes shrink, the use of metal-based dielectric films raises issues relative to the compatibility of the use of these materials and polycrystalline silicon (poly-Si), so far used as a gate electrode. A new class of metal-based gate electrodes is today considered to overcome issues such as depletion, cross-contamination . . . .

The application of metal silicon nitrides as a barrier layer sandwiched between a Cu interconnect or electrode and a low-k dielectric film is another example of the application of compounds that contain metal and silicon. The metal nitrides have a good conductivity and can also effectively prevent contamination of low-k dielectric film by Cu. Moreover, the low resistance of the barrier layer is an advantage from the standpoint of decreasing RC delay.
Metal silicon nitride films have heretofore been formed, for example, by CVD using ammonia and metal halide (e.g., TiCl₄, TaCl₅). This approach, however, requires a high thermal budget and a high process temperature (>650° C.) and is not compatible with back-end-of-line (BEOL) processes.
U.S. Pat. No. 6,602,783 discloses the use of ammonia and an amino metal precursor (e.g., TDMAT, TDEAT, TBTDET, TAIMATA) for metal nitride film formation by CVD The use of such amino metallic precursors has been found to improve the film properties of, for example, CVD-TiSiN films. It has also been found that the formation of metal nitride films doped with small amounts of silicon by CVD using an amino metallic precursor, silane SiH₄, and ammonia is advantageous in terms of improving the barrier properties. SiH₄, however, is a high pressure pyrophoric gas and SiH₄ leaks pose a substantial risk of causing damage. When, on the other hand, dialkylaminosilane Si(NR₁R₂)₄ is used as the silicon source in place of silane, one must deal with the strong potential of the incorporation of large amounts of carbon into the film and an increased barrier layer resistance. Nitrogen and/or silicon-based compounds have been found very effective for that purpose. Thus, it is desirable to develop new processes of depositing metallic films with the required electrical properties (adequate work function, high conductivity).

Of particular interest is therefore the formation of a transition metal-containing film (“MSiN”), which can be either a metal nitride, a metal silicide or a metal silicon nitride. Forming a metallic film typically involves feeding the relevant chemicals including a metal source, a silicon source, and a nitrogen source (collectively referred to herein as the “precursors”) in the proper relative amounts to a deposition device wherein a substrate is held at an elevated temperature. The precursors are fed to a deposition chamber through a “delivery system.” A “delivery system” is the system of measuring and controlling the amounts of the various precursors being fed to the deposition chamber. Various delivery systems are known to one skilled in the art. Once in the deposition chamber, the precursors react to deposit a film on the substrate in a “forming” step. A “forming” step or steps, as used in this application, is the step or steps wherein materials are deposited on the substrate or wherein the molecular composition or structure of the film on the substrate is modified. The “desired final composition” of the film is the precise chemical composition and atomic structure of the layer after completion of the last forming step. Compounds of tantalum, titanium and tungsten, either as metal, metal nitride, metal silicide or metal silicon nitride are the most promising barrier or electrode materials. The metal source for the forming process is typically a liquid precursor or a liquid precursor solution containing the desired metal in a solvent. Similarly, the silicon sources available today typically use a liquid precursor which may have a low vapor pressure. Different means of delivering the low vapor pressure silicon compound have been developed that may include vaporizers, or dilution of the precursor in an appropriate solvent.

When Atomic Layer Deposition (ALD) is used, the reactions should be self-terminated to allow a well-controlled process and therefore organic precursors might raise some issues such as chemical stability of the precursor itself, reactivity for nitridation and carbon content control. The use of metal halides has been therefore extensively studied.

U.S. Pat. No. 6,139,922 discloses thermal & plasma CVD of Ta, TaN, TaSi and TaSiN using fluorine-containing precursor. Examples disclose PECVD using TaF₅ with N₂/H₂ plasma and thermal CVD using TaF₅ with NH₃. U.S. Pat. No. 6,200,893 discloses a multi-step ALD process (3 steps for nitridation) of TaN using TaCl₅ with N₂/H₂ radicals or with NH/NH₂ radicals. More particularly, it discloses the use of hydrogen and the nitrogen radicals in various steps of the process. However, no process information is disclosed in the patent specification such as the type of plasma and the process temperature used to carry out such process.
U.S. Pat. No. 6,265,311—discloses PECVD of tantalum nitride using TaF₅ or TaCl₅ with N₂/H₂ plasma in deposition range of 300 to 500 C. Direct RF plasma (0.1-5.0 W/cm²) is used for the deposition. U.S. Pat. No. 6,268,288 discloses thermal CVD of TaN using TaF₅ or TaCl₅ in deposition range of 300 to 500 C, along with post-treatment of the film with hydrogen containing radicals created by the RF plasma. U.S. Pat. No. 6,410,433 discloses the use of thermal CVD of tantalum nitride using TaCl₅ with NH₃/H₂ gas in deposition range of 300 to 500 C.
U.S. Pat. No. 6,706,115 discloses thermal ALD of TaN using TaX₅ (X=Cl, Br, I) with NRₓH₃₋ₓ including ammonia, wherein tantalum nitride thin layers having low resistivity are obtained with a substrate temperature between 350 and 500° C.

The various documents cited hereabove relate to forming dielectric films: however, all the processes disclosed in these documents suffer from certain drawbacks;

Tantalum halides are known to be powders at ambient conditions. Among them, TaF₅ has the highest vapor pressure. However, the fluorine contained in this precursor is too aggressive to the layer underneath, especially in the case of high-k dielectrics.

TaCl₅ is a dimer, has a fair vapor pressure (0.3 Torr at 100° C.) but is solid and air sensitive, and therefore difficult to stably deliver and handle.

It is known for the man skilled in the art that the physical properties of a film are affected by the ratio of the metal (M) to silicon (Si) and to nitrogen ratio, or M/Si/N. It is desirable to be able to control the M/Si/N ratio over a broad range. Thus, it is important to be able to vary the metal and silicon feed independently to achieve the widest possible M/Si/N ratio range.

Some processes use a silicon source precursor said silicon source also containing some amount of the nitrogen that is to be deposited. The problem encountered is that changes in the nitrogen-containing silicon source precursor feed rate changes the total amount of the nitrogen fed to the process (due to the nitrogen contained in the silicon precursor). It makes it difficult to control the film composition during the deposition process because the silicon feed rate cannot be changed without also affecting the total amount of nitrogen being fed to the deposition chamber. Furthermore, the ratio of M/Si/N that can be fed is limited by the composition of the nitrogen in the silicon source precursor. Thus a change in the desired M/Si/N ratio may mean a need for changing the precursor solution being fed to the process.

Introducing a precursor having direct Ta—C bond or Ta—N(—C) σ-bond may also generate problems with the control of the film composition, as carbon in very large amount can be introduced. The carbon content with such precursors is frequently higher than nitrogen content. As a result, another parameter should be controlled, which makes difficult the tuning of the desired properties (work function, threshold voltage, conductivity . . . ). Nevertheless, carbon can have desirable effects on these properties, and it is desirable to be able to control the amount incorporated in the film.

For the foregoing reasons, it is desirable to form a film of the final desired composition in a single forming step. Furthermore, the film should minimize chlorine or any other halide content and optimize the carbon content in the molecular structure. It may be also desirable to use a metal source that is free of metal-carbon bonds or nitrogen-carbon bonds so the carbon source feed, the silicon source, the nitrogen source and the metal source feed may be independently controlled.

### SUMMARY

The present invention is directed to methods and compositions that satisfy the need to form a thin film with excellent electrical properties and high conformality. It avoids using multiple forming steps to assure uniform coverage and high conformality. The new chemistry proposed provides the benefit of optimum film characteristics by ALD, CVD or pulsed CVD mode deposition. Furthermore, the present invention provides a film that minimizes chlorine or other halogen content and allows the optimization of the carbon content, both of which can degrade the electrical properties of the film. In addition, the invention provides the ability to control the M/Si/N ratio in the films over a broad range without changing precursor solutions.

According to the invention, there is provided a method for forming a transition metal containing film onto a sample, comprising the steps of:
introducing a sample into a deposition chamber
heating said sample up to a desired temperature;
providing a liquid or solid transition metal source;
providing at least one precursor source, said precursor(s) source(s) being selected from the group essentially consisting of a silicon source, a carbon source, a nitrogen source, and/or a reducing source;
vaporizing said transition metal to form a vaporized transition metal source;
delivering said transition metal vapor to the chamber,
delivering at least one precursor vapor from the at least one precursor source to the chamber; and
forming a metallic film of the desired final composition onto said sample.

According to a preferred embodiment, the metal transition source comprises a chemical compound of the formula

MXₘ

Or

the adduct MXₘ, ABₙ

### Wherein:

M is a transition metal
X is an halogen, preferably Cl
m is the oxidation state of the transition metal
A is selected from the group consisting of O, S and N
B is a hydrogen or hydrocarbon chain comprising between one and sixteen carbon atoms, said chain being linear, branched or a cycle,
   n is the number of groups B bonded to A.

According to various embodiments of the invention:

M is a transition metal preferably an early transition metal and most preferably selected from the group consisting of Ta, Nb, Mo, W, Hf . . . the silicon source comprises a molecular structure terminated by at least one silyl (SiH₃) ligand such as trisilylamine, disilane or trisilane.

and/or
the nitrogen source is a molecule or radical of the formula NHₓ with x being equal to or lower than 3 or comprising a molecular structure terminated by at least one silyl ligand, such as trisilylamine, hexamethyldisilazane (also named bis(trimethylsilyl)amine).
   and/or
the reducing source is a molecule or radical of the formula Hₓ with x is equal to or lower than 2.
   and/or
the carbon source comprises comprises a C₁-C₁₆ linear, branched or cyclic hydrocarbon.

Preferably, the step of forming a metallic film shall be completed by using an atomic layer deposition process wherein the precursors are preferably sequentially introduced into the reactor.

According to an embodiment, the process of the invention is based on the use of a vapor phase silicon precursor in conjunction with a liquid phase metal precursor for the deposition of films of the desired stoichiometry. The vapor phase silicon precursor is sufficiently volatile at temperatures above 15° C. to supply the process as a vapor without the need of bubbling a carrier gas through a liquid or heating it in a vaporizer. This eliminates the control and quality problems associated with having to vaporize two precursors (a metal containing precursor and a silicon containing precursor) or to bubble a carrier gas through a liquid to feed the silicon source. In addition, the vapor phase silicon precursor is preferably not coordinated to a metal, allowing independent control over feeding of the metal source and the silicon source. Thus, the M/Si ratio can be easily varied over a wide range without having to mix new precursor solutions and recalibrate the process to the new precursor mixture. In a similar manner, the vapor phase nitrogen precursor is not coordinated to a metal allowing independent control over feeding of the metal source and the silicon source. Thus, the M/N ratio can be easily varied over a wide range without having to mix new precursor solutions and recalibrate the process to the new precursor mixture. Furthermore, the vapor phase silicon precursor is preferably carbon and halogen free, hence dramatically reducing the undesirable effects of carbon and halogens in the film. Finally, the current method according to the invention produces a film of the desired final composition in a single step.

The metal source is typically a liquid precursor or a liquid precursor solution. The liquid phase precursor is injected into a system that vaporizes it into a gas phase (forming a vaporized transition metal source). The vaporized precursor gas phase enters the deposition chamber where deposition occurs at an elevated temperature. The metal source is preferably essentially consisting of a metal bonded to 4 to 6 halogens. It is as well bonded with an electrically “neutral molecule” forming an adduct to form a liquid or a solid of low melting point. The neutral molecule is formed with an element such as sulphur, oxygen, nitrogen and is bonded to two or three alkyl groups. The adduct can decompose a temperature which is high enough so that the precursor can be delivered effectively either by a bubbler or a liquid injection system. It can decompose at low temperature so that the elements included in the neutral molecule may not be incorporated into the film. The neutral molecule itself needs to be stable at high enough temperature. Furthermore, the adduct is usually a monomer while the metal halide is usually a dimer, which results in a significant improvement of the vapor pressure.

The family of adducts is exemplified by the adduct TaCl₅,SEt₂, which decomposes at about 200 C into TaCl₅ and SEt₂, SEt₂ being stable up to temperature of at least 600 C.
TaCl₅,SEt₂ is a monomer while TaCl₅ is a dimer, which results in a significant improvement of the vapor pressure.

The silicon source of a film of the current invention is injected into the deposition chamber effectively preferably concurrent with the vaporized metal precursor. The silicon source is preferably in the vapor phase at process feed conditions. That is, the silicon source preferably flows from the source container through the feed measurement and control system as a vapor without the need to be vaporized or without using a carrier gas. However, an inert gas may be used to dilute the silicon mixture if needed to obtain even more accurate flow measurements. Preferably, the silicon source does not contain in its molecular structure any atom of chlorine and/or halogen, and/or deposition metals. More preferably, the silicon source does not contain any atom in its molecular structure of carbon. Most preferred silicon sources that are carbon and chlorine free are, without limitation, the following compounds or mixtures of the following compounds:

1) Trisilylamine;

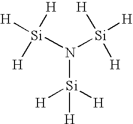

2) Disilylamine;

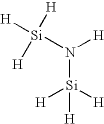

3) Silylamine;

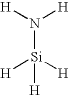

4) Tris(disilyl)amine;

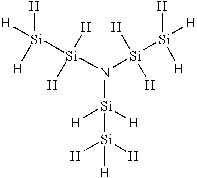

5) Aminodisilylamine;

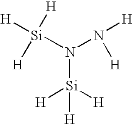

6) Tetrasilyldiamine, also called tetrasilylhydrazine; and

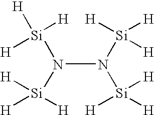

7) Disilane derivatives, wherein any H bonded to N may be replaced with a SiH₂—SiH₃

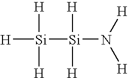

8) Trisilane and its derivatives.

The nitrogen containing gas may also be injected into the deposition chamber concurrently with the vaporized metal source and the silicon source. Preferred oxygen containing gases and nitrogen containing gases are free of carbon and/or chlorine in their molecular structures.

The reaction of the different precursors in the deposition chamber (reactor) leads to the formation of a film on the silicon substrate. The composition of the film can be precisely controlled by precisely controlling the flow rates of each of the precursors independently (and this by controlling the ratio of flow rates). The feed rates of the silicon and metal sources are independently controllable, thus the M/Si and M/N ratios of the resulting film can be controlled over a wide range without changing the composition of the metal source or the silicon source.

It might be desirable to introduce an hydrogen source either at any time during the deposition or during the post-treatment step to reduce the chlorine content incorporated in the film or to improve the film quality.

### BRIEF DESCRIPTION OF THE DRAWINGS

FIG. 1 is a flow chart of a Prior Art method for forming a MSiN film.

FIG. 2 is a flow chart of the steps of the method for forming a MSiN film.

FIG. 3 is a flow chart of the steps of the method for forming a MC film.

FIG. 4 is a flow chart of the steps of the method for forming a MNC film.

FIG. 5 is a flow chart of the steps of the method for forming a MSiNC film.

FIG. 6 is a flow chart of the steps of the method for forming a MSiC film.

FIG. 7 is a structural drawing of the CVD tool used in Example 1 of this invention.

FIG. 8 is a structural drawing of the CVD tool used in Example 2 of this invention.

FIG. 9 is a structural drawing of the CVD tool used in Examples 3 and the following ones of this invention.

### REFERENCE SYMBOLS

1 . . . silicon wafer
11 . . . deposition (CVD) chamber
12 . . . pump
13 . . . adsorber
21 . . . liquid container
22 . . . He gas
23 . . . liquid mass flow controller
24 . . . mass flow controller
25 . . . vaporizer
31 . . . cylinder
32 . . . mass flow controller
33 . . . N₂ gas
41 . . . Additional gas
42 . . . mass flow controller
43 . . . bubbler
51 . . . bubbler
52 . . . nitrogen source
53 . . . pressure regulator
54 . . . mass flow controller
55 . . . two-ways by-pass system
56 . . . flow control system
V3 . . . actuated valve
V4 . . . actuated valve
V5 . . . actuated valve

### EXAMPLES

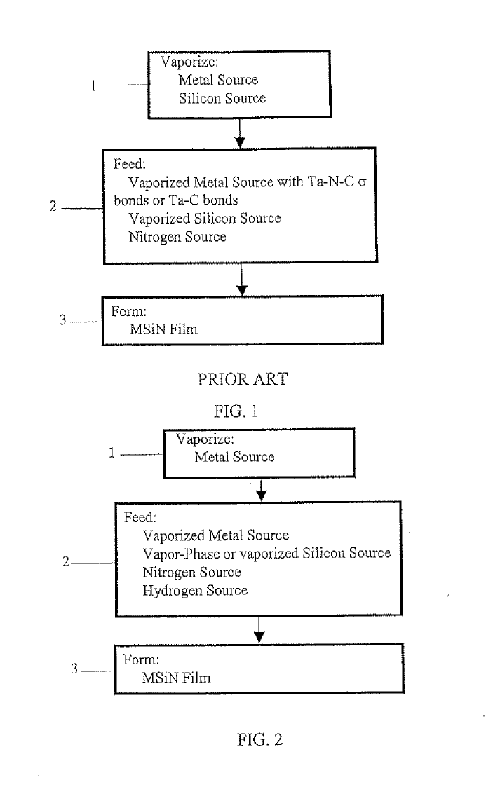

Referring to the transition metal-containing film deposition method of FIG. 1-6, the vaporizing step 1 comprises vaporizing a metal source to form a vaporized metal source. The metal source of one preferred embodiment is a precursor solution in liquid phase, preferably a dialkylamino, an alkoxy, and/or an inorganic compound of hafnium (Hf), zirconium (Zr), titanium (Ti), niobium (Nb), tantalum (Ta), molybdenum, (Mo), tungsten (W) or any other transition metal (M). Preparing and vaporizing the liquid phase metal precursor solution is carried out in commercially available equipment under appropriate conditions known to the man skilled in the art.

During the feed step 2 a silicon source, a nitrogen source, a carbon source, and a hydrogen source (collectively referred to as the precursors sources) are fed to a deposition chamber where a substrate (on which deposition is needed) is placed at an elevated temperature. The deposition chamber is typically maintained between about 300° C. to about 900° C. Preferably the surface of the work piece in the deposition chamber will be between about 500° C. to about 600° C. The feeding of the precursors is effectively concurrent (atomic layer deposition involves high-speed sequential pulses of feed materials).

During the feed step 2 of the transition metal-containing film deposition method of FIG. 1-6, the silicon source is controllably injected into the deposition chamber effectively concurrent with the vaporized metal source and the other precursors or silicon film components. In one preferred embodiment, a silicon source is in the vapor phase at process feed conditions. That is, the silicon source of one preferred embodiment has a vapor pressure of greater than approximately 50 torr at 20° C., sufficient to exist in the vapor phase in the feed control system without the need for vaporization or bubbler equipment in the delivery system. Trisilane and trisilylamine, two preferred silicon sources, may be stored as a liquid, but have sufficient vapor pressure (greater than 200 torr vapor pressure at 25° C.) to be in the vapor phase in the delivery system without the need to use a vaporizer or bubbler system. Because the silicon source is in the vapor phase, its flow rate can be accurately measured and controlled with conventional devices know in the art, and is not affected by deposits in a vaporizer or swings in feed conditions during vaporization of the silicon or metal source.

Preferably, the silicon source is absent carbon or chlorine in the molecular structure.

Preferably, the hydrogen and nitrogen gases are fed into the deposition chamber concurrently with the silicon source. Furthermore, the vaporized metal source is also fed concurrently in the feed step 2. Various preferred embodiments of the MSiNC method use nitrogen sources that are free of carbon and/or chlorine in their molecular structures. It is not required that the nitrogen source, the silicon source or the carbon source be fed as a separate stream. The nitrogen source can be the same as the silicon source or the carbon source. The nitrogen source of one preferred embodiment is ammonia. The nitrogen source of another preferred embodiment is trisilylamine. The nitrogen source is fed and controlled with devices known to one skilled in the art.

The deposition and reaction of precursors in the deposition chamber lead to the formation of the transition metal-containing film on the heated silicon substrate during the forming step 3. One preferred embodiment of a transition metal-containing film is a tantalum silicon carbonitride film formed by feeding a tantalum metal using a mixture of a metal source (such as TaCl₅, SEt₂), trisilylamine and/or an amine.

The composition of the transition metal-containing film can be controlled by varying the flow of each of the dielectric precursors independently during the feeding step 2. Particularly, the feed rate of the silicon source and the metal source are independently controllable because the silicon source does not contain any deposition metal. Thus, the silicon source feed rate can be varied independently of the metal source feed rate to affect the desired metal (M) to silicon (Si), to nitrogen and to carbon ratio. Similarly, the metal source feed rate can be varied without affecting the silicon source feed rate, also changing the M/Si/N ratio. Because the feed rate of the silicon, the nitrogen, the carbon and metal sources are independently controllable, the M/Si/N/C ratio of the resulting film is controllable over a wide range without changing the composition of the metal source or the silicon source.

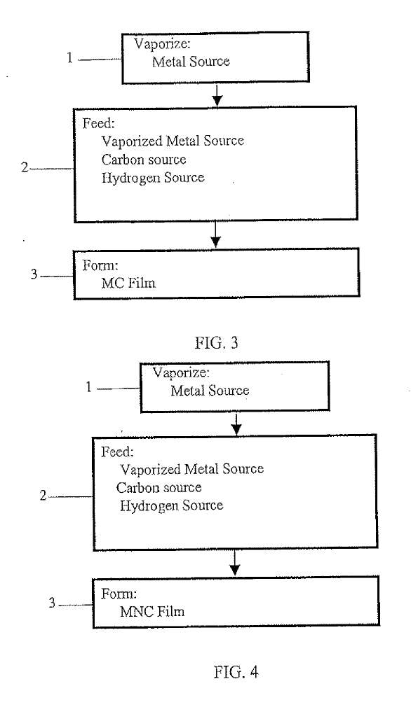

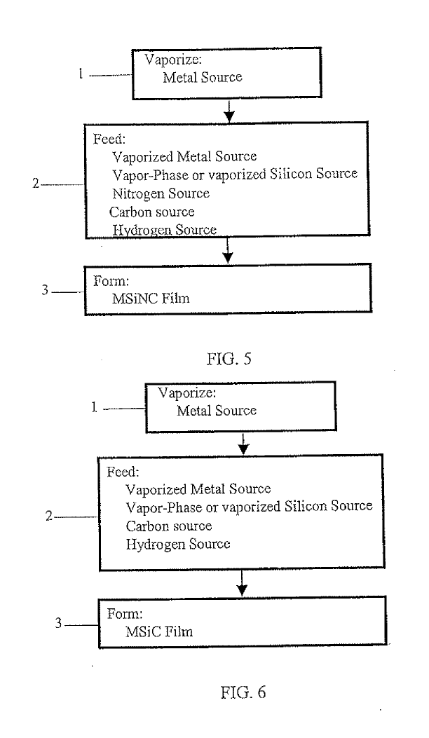

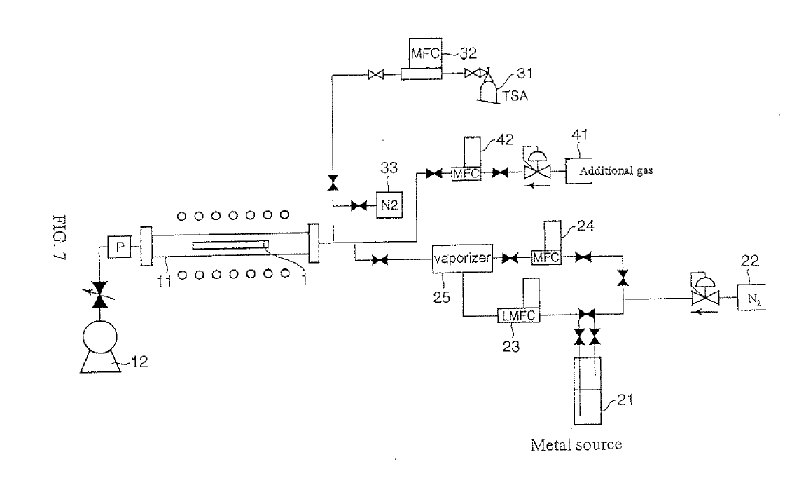

Although the present invention has been described in considerable detail with reference to certain preferred versions thereof, other versions are possible. For example, one or several sources can be omitted in order to obtain tantalum, tantalum silicide, tantalum silicon nitride (of FIG. 2), tantalum carbide (FIG. 3), tantalum nitride, tantalum carbonitride (FIG. 4), tantalum silicon carbide (of FIG. 6) . . . . The composition and method may be practiced in a process other than chemical vapor deposition or atomic layer deposition. In addition, the deposition of dielectric films can be accomplished at a variety of temperature and conditions. Furthermore, the invention may include a variety of metal, silicon, carbon and nitrogen sources known in the art. Therefore, the spirit and scope of the appended claims should not be limited to the description of one of the preferred versions contained herein. The intention of the applicants is to cover all modifications, equivalents, and alternatives falling within the spirit and scope of the invention as defined by the appended claims.

### EXAMPLES

Examples of the invention are described below with reference to the drawings.

### Example 1

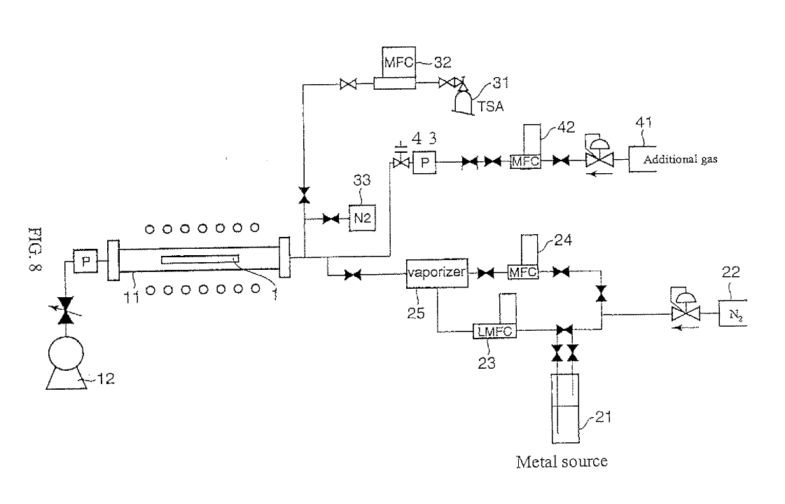

This example concerns the fabrication of tantalum silicon nitride films. The CVD tool used in this example is illustrated in FIG. 7. In FIG. 7, a silicon wafer 1 is introduced into a CVD chamber 11 and the desired film is formed onto the surface of the silicon wafer 1. The CVD chamber 11 is evacuated by a pump 12. The metal precursor, in this case tantalum pentachloride, diethyl sulfur adduct TaCl₅,SEt₂, is stored in a liquid container 21. Nitrogen gas from the nitrogen source 22 is used as the carrier gas for the TaCl₅,SEt₂. The TaCl₅,SEt₂ in the liquid container 21 is pulled out in liquid form by the nitrogen gas under pressure 22 through a liquid mass flow controller 23 and reaches the vaporizer 25 where it is vaporized and mixed if necessary with nitrogen from the nitrogen source 22 (or any other inert gas from any source) through the MFC 24. Nitrogen from nitrogen source 33 is also transported through a mass flow controller into the CVD chamber 11 along with trisilylamine (TSA) stored in a cylinder 31, and through mass flow controller 32 and with an additional gas 41 (hydrogen gas, a reducing source) fed through the pressure regulator 43 and the mass flow controller 42.

Thin films of tantalum silicon nitride films were produced under the following conditions using the described CVD tool.

Pressure=1 torr, temperature=600° C., TaCl₅,SEt₂ flow rate=0.5 ccm, N₂ flow rate (vaporizer)=20 sccm, TSA flow rate=5 sccm, H₂ flow rate=10 sccm, N₂ flow rate=100 sccm.

### Example 2

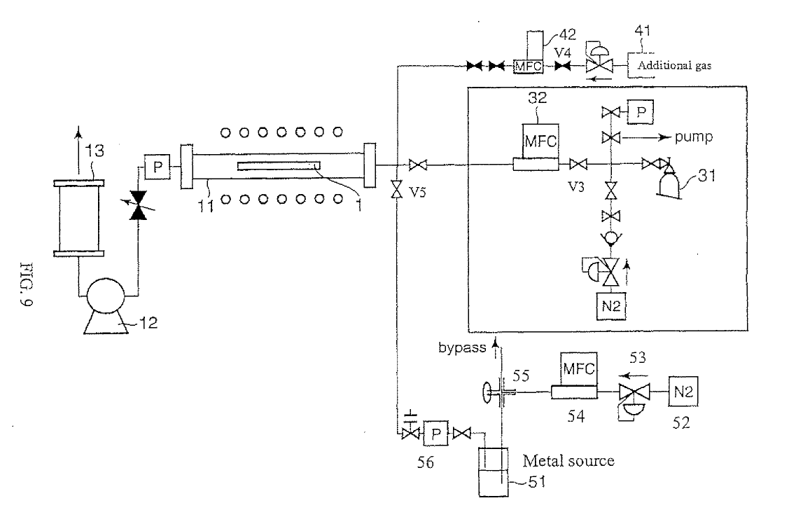

This example concerns the fabrication of tantalum silicon nitride films. The CVD tool used in this example is illustrated in FIG. 8. On FIG. 8, the same devices as on FIG. 7 bear the same numerical references. The CVD tool used in this example is illustrated in FIG. 7. In FIG. 8, a silicon wafer 1 is introduced into a CVD chamber 11 that is provided with heating means 2 over its circumference and the desired film is formed onto the surface of the silicon wafer 1. The CVD chamber 11 is evacuated by a pump 12. The metal precursor, in this case tantalum pentachloride, diethyl sulfur adduct TaCl₅,SEt₂, is stored in a liquid container 21. Nitrogen gas from the nitrogen source 22 is used as the carrier gas for the TaCl₅,SEt₂. The TaCl₅,SEt₂ in the liquid container 21 is pulled out in liquid form by the nitrogen gas under pressure 22 through a needle valve, a liquid mass flow controller 23 and reaches the vaporizer 25 where it is vaporized and mixed if necessary with nitrogen from the nitrogen source 22 (or any other inert gas from any source) through the MFC 24, Trisilylamine (TSA) stored in a cylinder 31 is also transported through a mass flow controller (MFC) 32 into the CVD chamber 11 along with an additional gas 41 (ammonia gas, a nitrogen source) fed through the controllable value 43 and the mass flow controller 42.

Thin films of tantalum silicon nitride films were produced under the following conditions using the described CVD tool.

Pressure=1 torr, temperature=500° C., TaCl₅,SEt₂ flow rate=0.5 ccm, TSA flow rate=5 sccm, NH₃ flow rate=20 sccm, N₂ flow rate=100 sccm.

### Example 3

This example concerns the fabrication of tantalum silicon nitride films. The CVD tool used in this example is illustrated in FIG. 9. In FIG. 9, a silicon wafer 1 is introduced into a CVD chamber 11 that is provided with heating means 2 over its circumference and the desired film is formed onto the surface of the silicon wafer 1. The CVD chamber 11 is evacuated by a pump 12. The metal precursor, in this case tantalum pentachloride, diethyl sulfur adduct TaCl₅,SEt₂, is stored in a liquid container 51. TaCl₅,SEt₂ vapor is fed to the CVD chamber 11 by bubbling nitrogen from the nitrogen source 52, said nitrogen flowing through the pressure regulator 53, the MFC 54, the two ways by-pass system 55, then through the liquid source 51. The mixture of metal precursor and/or nitrogen is then fed to the reactor through the control system 56. Trisilylamine (TSA) stored in a cylinder 31, is fed through mass flow controller 32. An additional gas, such as ammonia gas, 41 is fed through the mass flow controller 42.

Tantalum silicon nitride films were produced under the following conditions using the described CVD tool.

### Mode 3-1

Pressure=1 torr, temperature=470° C., TaCl₅,SEt₂ flow rate=0.5 sccm, TSA flow rate=4 sccm, NH₃ flow rate=5 sccm, N₂ flow rate=100 sccm. Using this set of conditions, tantalum silicon nitride with component ratios of Ta/Si=4:1 and Ta/N=1:1 was obtained at a film-formation rate of 10 Å/min.

### Mode 3-2

Pressure=1 torr, temperature=550° C., TaCl₅,SEt₂ flow rate=0.5 sccm, TSA flow rate=5 sccm, NH₃ flow rate=0 sccm, N₂ flow rate=100 sccm. This mode was the same as 1-1, with the exception that in this case no ammonia was flown.
Using this set of conditions, tantalum silicon nitride with component ratios of Ta/Si=6:1 and Ta/N=2.6:1 was obtained at a film-formation rate of 15 Å/min.

### Example 4

This example concerns the fabrication of silicon-doped titanium nitride films.
The CVD tool used in this example is illustrated in FIG. 9. The metal precursor, in this case titanium tetrachloride TiCl₄, is held in a bubbler 51 and TiCl₄ vapor is fed to the CVD chamber 11 as described in example 3. Trisilylamine (TSA) is held in the cylinder 31, and this TSA is transported through the mass flow controller 32 into the CVD chamber 11. The offgas from the CVD chamber is exhausted through an abatement system (adsorber) 13. Silicon-doped titanium nitride films were produced under the following conditions using the described CVD tool.

### Mode 4-1

Pressure=1 torr, temperature=625° C., TiCl₄ flow rate=5 sccm, TSA flow rate=4 sccm, N₂ flow rate=20 sccm, time=15 minutes.
According to AES analysis, the resulting film was titanium nitride with the stoichiometric composition that contained trace amounts of silicon. This film was about 4000 Å thick. The film-formation rate was approximately 270 Å/min.

### Mode 4-2

Pressure=1 torr, temperature=550° C. (this film-formation temperature was substantially lower than the prior-art film-formation temperatures using TiCl₄/NH₃), TiCl₄ flow rate=5 sccm, TSA flow rate=4 sccm, N₂ flow rate=20 sccm, time=15 minutes.
According to AES analysis, the resulting film was titanium nitride with the stoichiometric composition that contained trace amounts of silicon. This film was about 290 Å thick. The film-formation rate was approximately 19 Å/min.

### Example 5

### Tantalum Silicide Films

This example concerns the fabrication of tantalum silicon nitride films. The CVD tool used in this example is illustrated in FIG. 9. In FIG. 9, a silicon wafer 1 is introduced into a CVD chamber 11 that is provided and the desired film is formed onto the surface of the silicon wafer 1. The CVD chamber 11 is evacuated by a pump 12. The metal precursor, in this case tantalum pentachloride, diethyl sulfur adduct TaCl₅,SEt₂, is stored in a liquid container 51. TaCl₅,SEt₂ vapor is fed to the CVD chamber 11 by bubbling nitrogen from the nitrogen source 52, said nitrogen flowing through the pressure regulator 53, the MFC 54, the two ways by-pass system 55, then through the liquid source 51. The mixture of metal precursor and/or nitrogen is then fed to the reactor through the control system 56, Trisilane stored in a cylinder 31, is fed through mass flow controller 32. An additional gas, here ammonia gas (nitrogen source), 41 is fed through the mass flow controller 42.

Tantalum silicon nitride films were produced under the following conditions using the described CVD tool:

Pressure=1 torr, temperature=430° C., TaCl₅,SEt₂ flow rate=0.5 sccm, Trisilane flow rate=5 sccm, NH₃ flow rate=5 sccm, N₂ flow rate=120 sccm.
Using this set of conditions, tantalum silicon nitride with component ratios of Ta/Si=4:5 and Ta/N=4:1 was obtained at a film-formation rate of 10 Å/min.

### Example 6

### Deposition of Tantalum Silicon Carbonitride

The CVD tool used in this example is illustrated in FIG. 9. In FIG. 9, a silicon wafer 1 is introduced into a CVD chamber 11 that is provided and the desired film is formed onto the surface of the silicon wafer 1. The CVD chamber 11 is evacuated by a pump 12. The metal precursor, in this case tantalum pentachloride, diethyl sulfur adduct TaCl₅,SEt₂, is stored in a liquid container 51. TaCl₅,SEt₂ vapor is fed to the CVD chamber 11 by bubbling nitrogen from the nitrogen source 52, said nitrogen flowing through the pressure regulator 53, the MFC 54, the two ways by-pass system 55, then through the liquid source 51. The mixture of metal precursor and/or nitrogen is then fed to the reactor through the control system 56. Trisilane stored in a cylinder 31, is fed through mass flow controller 32. An additional gas, here monomethylamine (MMA) gas (carbon and nitrogen source), 41 is fed through the mass flow controller 42.

Tantalum silicon carbonitride films were produced under the following conditions using the described CVD tool:

Pressure=1 torr, temperature=430° C., TaCl₅,SEt₂ flow rate=0.5 sccm, Trisilane flow rate=5 sccm, MMA flow rate=5 sccm, N₂ flow rate=120 sccm.

Using this set of conditions, tantalum silicon nitride with component ratios of Ta/Si=1:4,Ta/N=2:1, Ta/C=2:1 was obtained.

### Example 7

### Deposition of Tantalum Carbonitride

The CVD tool used in this example is illustrated in FIG. 9. In FIG. 9, a silicon wafer 1 is introduced into a CVD chamber 11 that is provided and the desired film is formed onto the surface of the silicon wafer 1. The CVD chamber 11 is evacuated by a pump 12. The metal precursor, in this case tantalum pentachloride, diethyl sulfur adduct TaCl₅,SEt₂, is stored in a liquid container 51. TaCl₅,SEt₂ vapor is fed to the CVD chamber 11 by bubbling nitrogen from the nitrogen source 52, said nitrogen flowing through the pressure regulator 53, the MFC 54, the two ways by-pass system 55, then through the liquid source 51. The mixture of metal precursor and/or nitrogen is then fed to the reactor through the control system 56. Hydrogen stored in a cylinder 31, is fed through mass flow controller 32. An additional gas, here monomethylamine (MMA) gas (carbon and nitrogen source), 41 is fed through the mass flow controller 42.

Tantalum carbonitride films were produced under the following conditions using the described CVD tool:

Pressure=5 torr, temperature=600° C., TaCl₅,SEt₂ flow rate=0.5 sccm, H₂ flow rate=5 sccm, MMA flow rate=5 sccm, N₂ flow rate=200 sccm.

Using this set of conditions, tantalum silicon nitride with component ratios of Ta/N=1:1, Ta/C=4:1 was obtained.

### Example 8

### Atomic Layer Deposition of Tantalum Silicon Nitride Films

This example concerns the fabrication of tantalum silicon nitride films. The deposition tool used in this example is illustrated in FIG. 9. In FIG. 9, a silicon wafer 1 is introduced into a deposition chamber 11 that is provided with heating means 2 over its circumference and the desired film is formed onto the surface of the silicon wafer 1. The deposition chamber 11 is evacuated by a pump 12. The metal precursor, in this case tantalum pentachloride, diethyl sulfur adduct TaCl₅,SEt₂, is stored in a liquid container 51. TaCl₅,SEt₂ vapor is fed to the deposition chamber 11 by bubbling nitrogen from the nitrogen source 52, said nitrogen flowing through the pressure regulator 53, the MFC 54, the two ways by-pass system 55, then through the liquid source 51. The mixture of metal precursor and/or nitrogen is then fed to the reactor through the control system 56, sequentially introduced into the deposition chamber 11 by opening/closing the actuated valve V5. Trisilylamine (TSA) stored in a cylinder 31, is fed through mass flow controller 32, sequentially introduced into the deposition chamber 11 by opening/closing the actuated valve V3. An additional gas 41, none in this case, can be fed through the mass flow controller 42, sequentially introduced into the deposition chamber 11 by opening/closing the actuated valve V4.
Tantalum silicon nitride films were produced under the following conditions using the described deposition tool.
Pressure=1 torr, temperature=400° C., TaCl₅,SEt₂ flow rate=0.25 sccm, TSA flow rate=1 sccm, N₂ flow rate=200 sccm.

Using this set of conditions, tantalum silicon nitride with component ratios of Ta/N=1:1, Ta/Si=1:8 was obtained.

1-10. (canceled)

11. A method for forming a transition metal containing film onto a sample, comprising the steps of.
a) introducing a sample into a deposition chamber;
b) heating said sample up to a desired temperature;
c) providing a liquid or solid transition metal source;
d) providing at least one precursor source, said precursor(s) source(s) being selected from the group essentially consisting of a silicon source, a carbon source, a nitrogen source, and/or a reducing source;
e) vaporizing said transition metal to form a vaporized transition metal source;
f) delivering said transition metal vapor to the chamber;
g) delivering at least one precursor vapor from the at least one precursor source to the chamber; and
h) forming a metallic film of the desired final composition onto said sample.

12. The method of claim 11, wherein the metal transition source comprises a chemical compound of the formula.
MXₘ
Or
MXₘ, ABₙ
wherein
M is a transition metal;
X is an halogen, preferably Cl;
m is the oxidation state of the transition metal;
A is selected from the group consisting of O, S and N;
B is a hydrocarbon chain comprising between one and sixteen carbon atoms, said chain being linear, branched or a cycle; and
n is a number of groups B bonded to A.

13. The method of claim 12, wherein M is a transition metal. Preferably an early transition metal and most preferably selected from the group consisting of early transition metals. Ta, Nb, Mo, W, Hf.

14. The method of claim 11, wherein said silicon source comprises a molecular structure terminated by at least one silyl (SiH₃) ligand, preferably trisilylamine N(SiH₃)₃, silane H(SiH₃), disilane (SiH₃)₂, trisilane SiH₂(SiH₃)₂

15. The method of claim 11, wherein said nitrogen source is a molecule or radical of the formula NHₓ with x being equal to or lower than 3 or comprising a molecular structure terminated by at least one silyl ligand, preferably trisilylamine N(SiH₃)₃, hexamethyldisilazane (also named bis(trimethylsilyl)amine) HN(Si(CH₃)₃)₂.

16. The method of claim 11, wherein said reducing source is a molecule or radical of the formula Hₓ, wherein x is equal to or lower than 2.

17. The method of claim 11, wherein said carbon source comprises a C1-C16 linear, branched or cyclic hydrocarbon into the reactor, preferably an organic amine, most preferably monomethylamine, dimethylamine, monopropylamine.

18. The method of claim 11, wherein said forming a metallic film step is completed by using an atomic layer deposition process wherein the precursors are preferably sequentially introduced.

19. The method of claim 11, wherein said source comprises a molecular structure including two or three elements among silicon, nitrogen and carbon, preferably an organic aminosilane such as SiH₂(NMe₂)₂, SiH(NMe₂)₃, Si(NMe₂)₄, SiH₂(NEt₂)₂, SiH(NEt₂)₃, Si(NEt₂)₄

20. The method of claim 11, wherein said forming a metallic film step is performed in a temperature range comprised between 250° and 650° C., and a pressure range comprised between 0.01 to 1000 Torr.
